(19) United States
(12) Patent Application Publication
(10) Pub. No.: US 2024/0332273 A1
(43) Pub. Date: Oct. 3, 2024

(54) OPTICAL MODULE AND FLEXIBLE SUBSTRATE

(71) Applicant: SUMITOMO ELECTRIC INDUSTRIES, LTD., Osaka (JP)

(72) Inventors: Hiroshi UEMURA, Osaka (JP); Keiji TANAKA, Osaka (JP); Seiji KUMAGAI, Osaka (JP)

(21) Appl. No.: 18/609,318

(22) Filed: Mar. 19, 2024

(30) Foreign Application Priority Data
Mar. 31, 2023 (JP) 2023-058740

(51) Int. Cl. H01L 25/16; G02F 1/01; G02F 1/21; H01L 23/00; H01L 23/498; H10N 19/00

(52) U.S. Cl. CPC H01L 25/167; G02F 1/0102; G02F 1/212; H01L 23/49838; H01L 23/4985; H01L 24/16; H01L 24/17; H10N 19/00; G02F 1/218; G02F 2202/102; H01L 24/49; H01L 24/73; H01L 2224/17155; H01L 2224/48091; H01L 2224/48225; H01L 2224/48227; H01L 2224/49175; H01L 2224/73207; H01L 2924/1426

(57) ABSTRACT

An optical module according to one embodiment includes: a package having a first surface and a second surface; a driver IC mounted on the first surface via a heat sink block; an optical circuit element mounted on the second surface via a temperature adjustment element; and a flexible substrate mounted on the driver IC and the optical circuit element, and electrically connected to the driver IC and the optical circuit element. The flexible substrate includes a main body extending in a first direction and a second direction intersecting the first direction, and a wiring formed on the main body. The main body includes a first end facing an optical circuit element. The wiring includes a first lead portion protruding from the first end to an outside of the main body along the first direction. The first lead portion is connected to the optical circuit element.

### CROSS-REFERENCE TO RELATED APPLICATION

This application claims priority from Japanese Patent Application No. 2023-058740, filed on Mar. 31, 2023, the entire subject matter of which is incorporated herein by reference.

### TECHNICAL FIELD

The present disclosure relates to an optical module and a flexible substrate.

### BACKGROUND

Japanese Unexamined Patent Publication No. 2018-189699 describes an optical transmitter. The optical transmitter includes a Mach-Zehnder modulator, a driver IC, and a wiring substrate. The wiring substrate connects the Mach-Zehnder modulator and the driver IC to each other through flip-chip mounting. The wiring substrate is a flexible substrate made of silicon dioxide (SiO₂) or resin. In the optical transmitter, an inclination of the wiring substrate with respect to the Mach-Zehnder modulator and the driver IC is within ±3°.

Specification of U.S. Patent Application Publication No. 2015/0180580 describes an optical transmitter including an interconnect bridge assembly including a substrate. The substrate of the interconnect bridge assembly electrically connects a modulator driver and a control IC to each other. The substrate is made of a material having flexibility and elasticity. Accordingly, the substrate absorbs a difference between a height of the modulator driver and a height of the control IC.

### SUMMARY

An optical module according to the present disclosure includes: a package having a first surface and a second surface parallel to the first surface; a driver IC mounted on the first surface via a heat sink block; an optical circuit element mounted on the second surface via a temperature adjustment element; and a flexible substrate mounted on the driver IC and the optical circuit element, and electrically connected to the driver IC and the optical circuit element. The flexible substrate includes a main body extending in a first direction and a second direction intersecting the first direction, and a wiring formed on the main body. The main body includes a first end facing the optical circuit element. The wiring includes a first lead portion protruding from the first end to an outside of the main body along the first direction. The first lead portion is connected to the optical circuit element.

### BRIEF DESCRIPTION OF THE DRAWINGS

FIG. 1 is a plan view showing an internal structure of an optical module according to an embodiment.

FIG. 2 is a longitudinal sectional view of the optical module according to the embodiment.

FIG. 3 is a plan view showing a flexible substrate, a driver IC, an optical circuit element, and a package according to the embodiment.

FIG. 4 shows a cross-sectional view taken along line A-A of FIG. 3, and an enlarged schematic view of the flexible substrate.

FIG. 5 is a plan view showing the flexible substrate according to the embodiment.

FIG. 6 is a cross-sectional view taken along line B-B of FIG. 5.

FIG. 7 is a cross-sectional view taken along line C-C of FIG. 5.

FIG. 8 shows a cross-sectional view taken along line D-D of FIG. 3, and a cross-sectional view taken along line E-E of FIG. 3.

FIG. 9 is a plan view showing a flexible substrate, a driver IC, an optical circuit element, and a package according to a first modification example.

FIG. 10 is a cross-sectional view taken along line F-F of FIG. 9.

FIG. 11 is a plan view showing a flexible substrate, a driver IC, an optical circuit element, and a package according to a second modification example.

FIG. 12 is a cross-sectional view taken along line G-G of FIG. 11.

FIG. 13 is a plan view showing a flexible substrate, a driver IC, an optical circuit element, and a package according to a third modification example.

FIG. 14 is a cross-sectional view taken along line H-H of FIG. 13.

### DETAILED DESCRIPTION

For example, a driver IC and an optical circuit element may be affected by stress caused by expansion or contraction due to a change in temperature in a state where the driver IC and the optical circuit element are accommodated in a housing. Therefore, it is required to protect the driver IC and the optical circuit element from the influence of stress, and to enable signal transmission between the driver IC and the optical circuit element.

An object of the present disclosure is to provide an optical module and a flexible substrate capable of improving the robustness of electrical connections between a driver IC and an optical circuit element.

According to the present disclosure, it is possible to improve the robustness of electrical connection between the driver IC and the optical circuit element.

### Description of Embodiment of Present Disclosure

First, contents of an embodiment of an optical module and a flexible substrate according to the present disclosure will be listed and described. (1) An optical module according to one embodiment includes: a package having a first surface and a second surface parallel to the first surface; a driver IC mounted on the first surface via a heat sink block; an optical circuit element mounted on the second surface via a temperature adjustment element; and a flexible substrate mounted on the driver IC and the optical circuit element, and electrically connected to the driver IC and the optical circuit element. The flexible substrate includes a main body extending in a first direction and a second direction intersecting the first direction, and a wiring formed on the main body. The main body includes a first end facing the optical circuit element. The wiring includes a first lead portion protruding from the first end to an outside of the main body along the first direction. The first lead portion is connected to the optical circuit element.

A flexible substrate according to one embodiment includes: a main body extending in a first direction and a second direction intersecting the first direction; and a wiring formed on the main body. The main body includes a first end facing an optical circuit element. The wiring includes a first lead portion protruding from the first end to an outside of the main body along the first direction. The first lead portion is connected to the optical circuit element.

The optical module and the flexible substrate include the main body and the wiring, and the main body includes the first end facing the optical circuit element. The wiring includes the first lead portion. The first lead portion protrudes from the first end of the main body to the outside of the main body along the first direction, and is connected to the optical circuit element. By connecting the first lead portion of the wiring of the flexible substrate to the optical circuit element, the first lead portion protruding from the first end is flexed even when a change in temperature or the like occurs, so that the influence of stress on the driver IC and the optical circuit element can be reduced. Therefore, the driver IC and the optical circuit element can be protected from the influence of stress.

(2) In the above (1), a flexibility of the first lead portion may be larger than a flexibility of the main body. In this case, since the first lead portion can be flexed more greatly when a change in temperature or the like occurs, the influence of stress on the driver IC and the optical circuit element can be further reduced.

(3) In the above (1) or (2), the first lead portion may include a first coupling portion connected to the optical circuit element via a bump formed on the optical circuit element. In this case, since the first lead portion of the flexible substrate is connected to the optical circuit element via the bump, the influence of stress on the optical circuit element can be further reduced.

(4) In any of the above (1) to (3), the flexible substrate may include reinforcing portions protruding from the main body, and disposed to interpose the first lead portion between the reinforcing portions along the second direction. The reinforcing portions may be connected to the optical circuit element. In this case, the connection of the flexible substrate to the optical circuit element can be reinforced.

(5) In the above (4), the reinforcing portions may include dummy wirings. In this case, the difference in linear expansion coefficient between the reinforcing portions and the first lead portion and between the reinforcing portions and the second lead portion can be reduced, and a force applied to the wiring can be effectively reduced in a wide temperature range.

(6) In any of the above (1) to (5), the main body may include a second end opposite to the first end, and the wiring may include a second lead portion protruding from the second end to the outside of the main body along the first direction. The second lead portion may be connected to the driver IC. In this case, the main body includes the second end facing the driver IC, and the wiring includes the second lead portion. The second lead portion protrudes from the second end of the main body to the outside of the main body along the first direction, and is connected to the driver IC. By connecting the second lead portion of the wiring of the flexible substrate to the driver IC, the second lead portion protruding from the second end is flexed even when a change in temperature or the like occurs, so that the influence of stress on the driver IC and the optical circuit element can be reduced.

(7) In the above (6), the first lead portion may include a first coupling portion connected to the optical circuit element via a bump formed on the optical circuit element. The second lead portion may include a second coupling portion connected to the driver IC via a bump formed on the driver IC. An inclination of a straight line passing through the first coupling portion and the second coupling portion with respect to the first surface may be 10° or less. In this case, the driver IC and the optical circuit element can be more reliably protected from the influence of stress.

(8) In the above (7), the first coupling portion and the second coupling portion may be covered with resin. In this case, the first coupling portion and the second coupling portion can be further strengthened.

(9) An optical module according to another embodiment includes: a package having a first surface and a second surface parallel to the first surface; a driver IC mounted on the first surface via a heat sink block; an optical circuit element mounted on the second surface via a temperature adjustment element; and a flexible substrate mounted on the driver IC and the optical circuit element, and electrically connected to the driver IC and the optical circuit element. The flexible substrate includes a main body extending in a first direction and a second direction intersecting the first direction, and a wiring formed on the main body. The main body includes a second end facing the driver IC. The wiring includes a second lead portion protruding from the second end to an outside of the main body along the first direction. The second lead portion is connected to the driver IC.

(11) A flexible substrate according to another embodiment includes: a main body extending in a first direction and a second direction intersecting the first direction; and a wiring formed on the main body. The main body includes a second end facing a driver IC. The wiring includes a second lead portion protruding from the second end to an outside of the main body along the first direction. The second lead portion is connected to the driver IC.

In the optical module and the flexible substrate, the main body includes the second end facing the driver IC, and the wiring includes the second lead portion. The second lead portion protrudes from the second end of the main body to the outside of the main body along the first direction, and is connected to the driver IC. By connecting the second lead portion of the wiring of the flexible substrate to the driver IC, the second lead portion protruding from the second end is flexed even when a change in temperature or the like occurs, so that the influence of stress on the driver IC and the optical circuit element can be reduced. Therefore, the driver IC and the optical circuit element can be protected from the influence of stress.

### Details of Embodiment of Present Disclosure

Various examples of optical modules according to an embodiment will be described below with reference to the drawings. Incidentally, it is intended that the present invention is not limited to the following examples and includes all changes implied by the claims and within the scope equivalent to the claims. In the description of the drawings, the same or corresponding elements are denoted by the same reference signs, and duplicate descriptions will be omitted as appropriate. The drawings may be depicted partially in a simplified or exaggerated manner for ease of understanding, and dimensional ratios, angles, and the like are not limited to those shown in the drawings.

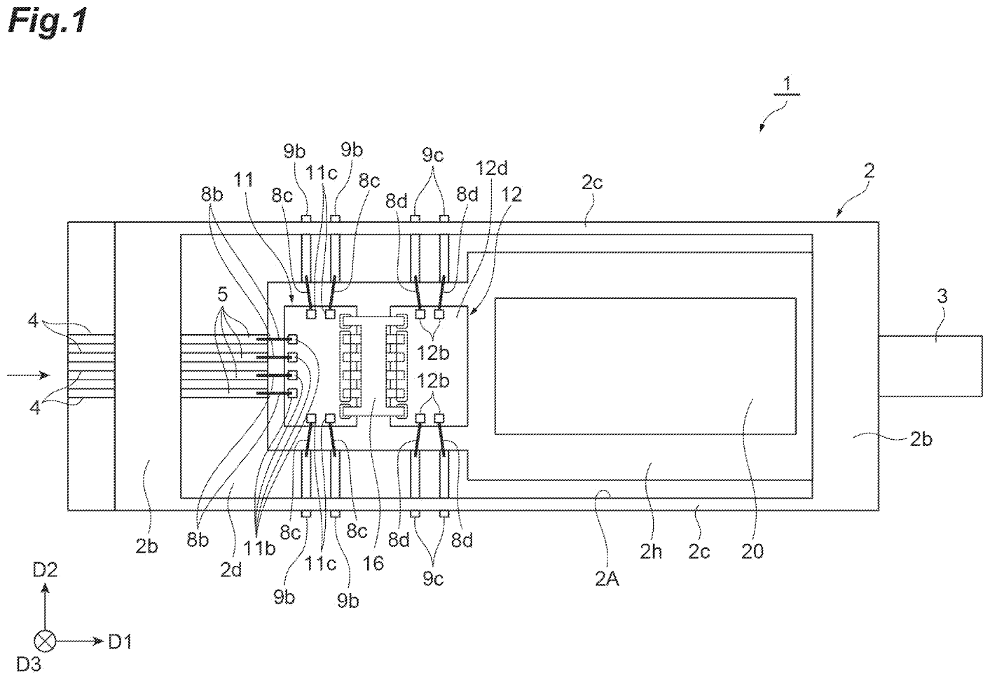

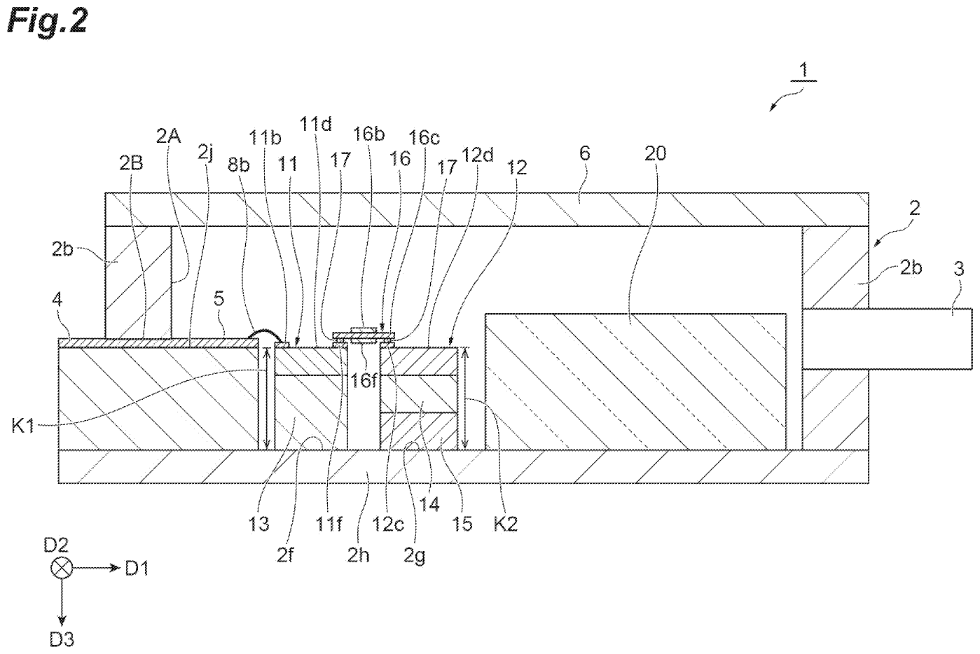

FIG. 1 is a plan view showing an internal structure of an optical module 1 according to the present embodiment. FIG. 2 is a longitudinal sectional view showing the optical module 1. As shown in FIGS. 1 and 2, the optical module 1 is, for example, a transmitter optical sub-assembly (TOSA) including a package 2 having a rectangular parallelepiped shape, an optical connector 3, and a terminal 4. The optical module 1 may be, for example, a coherent driver module (CDM). The package 2 is made of, for example, ceramic. The package 2 extends in a first direction D1 that is a longitudinal direction of the package 2, a second direction D2 that is a width direction of the package 2, and a third direction D3 that is a height direction of the package 2. The first direction D1, the second direction D2, and the third direction D3 are orthogonal to each other.

The package 2 includes a pair of first side walls 2b located at end portions in the first direction D1; a pair of second side walls 2c located at end portions in the second direction D2; and a bottom wall 2h located at one end in the third direction D3. An internal space 2A of the package 2 is defined in a region surrounded by the pair of first side walls 2b, the pair of second side walls 2c, and the bottom wall 2h. Components of the optical module 1 are accommodated in the internal space 2A. The optical module 1 further includes a lid 6 that seals the internal space 2A. The lid 6 is made of, for example, metal. FIG. 1 shows the internal space 2A of the package 2 with the lid 6 omitted in a plan view seen in the third direction D3.

A driver IC 11, an optical circuit element 12, and an optical component 20 are provided in the internal space 2A. For example, the optical circuit element 12 is an optical modulator. The driver IC 11 is, for example, such that an electrical circuit is formed on a silicon (Si) substrate using SiGe bipolar complementary metal oxide semiconductor (BiCMOS) process, and amplifies an electrical signal supplied from the terminal 4, and supplies the amplified electrical signal to the optical circuit element 12.

The driver IC 11 supplies an electrical signal to the optical circuit element 12. The optical circuit element 12 is, for example, such that a Mach-Zehnder interferometer is formed on an indium phosphide (InP) substrate, and modulates an optical signal supplied from the outside, based on the electrical signal supplied from the driver IC 11, and outputs the modulated optical signal. A modulation rate of the optical signal is, for example, 200 GBd. The electrical signal supplied from the driver IC 11 to the optical circuit element 12 passes through, for example, transmission lines formed in an electrical signal output unit of the driver IC 11 and an electrical signal input unit of the optical circuit element 12. These transmission lines may have substantially equal characteristic impedance, and the characteristic impedance is, for example, 60Ω differentially. A length of the driver IC 11 in the first direction D1 and a length of the optical circuit element 12 in the first direction D1 are, for example, 2 mm. A length of the driver IC 11 in the second direction D2 and a length of the optical circuit element 12 in the second direction D2 are, for example, 4 mm.

The package 2 has a heat sink plate (heat sink member). For example, the bottom wall 2h is formed of a heat sink plate. The heat sink plate is made of, for example, copper-tungsten (CuW). The heat sink plate may be made of, for example, a metal material other than CuW. Hereinafter, the bottom wall 2h is also referred to as a heat sink plate. The driver IC 11 is mounted on the heat sink plate (heat sink member) via a heat sink block 13. The heat sink block 13 is bonded to a first surface 2f of the package 2. The driver IC 11 is bonded to the heat sink block, for example, using a thermally conductive adhesive (not shown) such as silver paste. An alloy solder such as gold-tin (AuSn) solder or tin-silver-copper (SnAgCu) solder may be used instead of the thermally conductive adhesive. Similarly, the heat sink block 13 is bonded to the first surface 2f of the package 2, for example, using a thermally conductive adhesive. The heat sink block 13 may be made of, for example, metal or ceramic. In addition, the heat sink block 13 may be made of aluminum nitride.

The optical circuit element 12 is mounted on the bottom wall 2h, for example, via a thermoelectric cooler (TEC) 15 that is a temperature adjustment element. The TEC 15 is bonded to a second surface 2g of the package 2. For example, the first surface 2f and the second surface 2g are formed on the bottom wall 2h. The second surface 2g is a surface parallel to the first surface 2f. For example, the second surface 2g is located on the same plane as the first surface 2f. A spacer 14 is provided between the optical circuit element 12 and the TEC 15. The optical circuit element 12 is bonded to the spacer 14, for example, using a thermally conductive adhesive. The spacer 14 is bonded to the TEC 15, for example, using a thermally conductive adhesive. The TEC 15 is bonded to the second surface 2g of the package 2, for example, using a thermally conductive adhesive. The spacer 14 may be provided between the TEC 15 and the bottom wall 2h instead of between the optical circuit element 12 and the TEC 15. A plurality of the spacers 14 may be provided. The spacer 14 may be made of, for example, metal or ceramic. In addition, the spacer 14 may be made of aluminum nitride. For example, an optical component other than the optical circuit element 12 may be mounted on the spacer 14. In addition, the spacer 14 can also be omitted.

For example, the optical component 20 includes at least one of a lens, a mirror, a beam splitter, and an optical filter. The optical component 20 inputs and outputs an optical signal to and from the optical circuit element 12. The optical connector 3 is provided on one of the pair of first side walls 2b. The optical connector 3 inputs and outputs an optical signal to and from the optical component 20. Incidentally, regarding direction, a direction in which light is output from the optical connector 3 to the outside of the package 2 may be referred to as the front, the front side, or forward, and a direction opposite to the front, the front side, or forward may be referred to as the rear, the rear side, or rearward. For example, light output from the optical connector 3 to the rear, the rear side, or rearward is input to the optical component 20. However, these directions are defined for convenience of description, and do not limit directions in which the components are disposed.

For example, the package 2 includes electrical wirings 2B. The electrical wirings 2B are, for example, a feed-through electrical wirings that penetrates through the first side wall 2b (rear wall) on the rear side of the package 2 while maintaining the hermeticity (airtightness) of the internal space 2A. A part of each electrical wiring 2B is exposed to the outside of the package 2. A plurality of the terminals 4 for electrical connection with an external device are disposed at one end (one end outside the package 2) of each of the electrical wirings 2B to align along the second direction D2. In addition, a plurality of terminals 5 for electrical connection with the driver IC 11 are disposed at the other end (one end inside the package 2) of each of the electrical wirings 2B to align along the second direction D2.

The package 2 has a fifth surface 2j on which the electrical wirings 2B are formed, and the terminals 4 and the terminals 5 are further provided on the fifth surface 2j. The terminals 4 and the terminals 5 are electrically connected to each other via each electrical wiring 2B. Therefore, electrical signals can be exchanged between the outside and the inside (internal space 2A) of the package 2 via the electrical wirings 2B. The electrical signals include, for example, a power supply voltage and a ground voltage (ground potential) in addition to an analog signal and a digital signal. The fifth surface 2j is a surface parallel to the first surface 2f. In the internal space 2A, each of the plurality of terminals 5 is electrically connected to a pad 11b of the driver IC 11 via a bonding wire 8b. The driver IC 11 has a third surface 11d opposite to the heat sink block 13, and the pad 11b is provided on the third surface 11d. In addition, a circuit (not shown) of the driver IC 11 is also formed on the third surface 11d.

The optical module 1 includes a plurality of terminals 9b and a plurality of terminals 9c extending along the second direction D2 and exposed to the outside of the package 2. Each of the terminals 9b and the terminals 9c is exposed to the outside of the package 2 on each of the pair of second side walls 2c. Each of the plurality of terminals 9b is electrically connected to a pad 11c of the driver IC 11 via a bonding wire 8c. The pad 11c is provided on the third surface 11d of the driver IC 11. Incidentally, the terminals 9b and the terminals 9c may be provided only on one of the pair of second side walls 2c.

Each of the plurality of terminals 9c is electrically connected to a pad 12b of the optical circuit element 12 via a bonding wire 8d. The optical circuit element 12 has a fourth surface 12d opposite to the TEC 15, and the pad 12b is provided on the fourth surface 12d of the optical circuit element 12. In addition, a circuit (not shown) of the optical circuit element 12 is also formed on the fourth surface 12d. As described above, electrical signals are supplied to the optical module 1 via the terminals 4 or the terminals 9b and 9c, and the electrical signals are supplied to the driver IC 11 or the optical circuit element 12 via the bonding wires 8b, 8c, and 8d.

The optical circuit element 12 is formed, for example, using an InP compound semiconductor, and a linear expansion coefficient of the optical circuit element 12 is, for example, 4.5 ppm/° C. The temperature of the optical circuit element 12 is controlled to be constant by the TEC 15. The driver IC 11 is formed on, for example, a Si substrate, and a linear expansion coefficient of the driver IC 11 is, for example, 3 to 4 ppm/° C. The temperature of the driver IC 11 changes depending on the external temperature of the optical module 1, the power consumption of the driver IC 11, and the thermal resistance between the heat sink block 13 and the bottom wall 2h. The bottom wall 2h is made of, for example, CuW, and a linear expansion coefficient is 6 to 7 ppm/° C. In such a manner, since the linear expansion coefficients and temperatures of the components constituting the optical module 1 are different, the positions of the driver IC 11 and the optical circuit element 12 in the first direction D1, the second direction D2, and the third direction D3 can be changed depending on the external temperature. The optical module 1 includes a flexible substrate 16 that electrically connects the driver IC 11 and the optical circuit element 12 to each other.

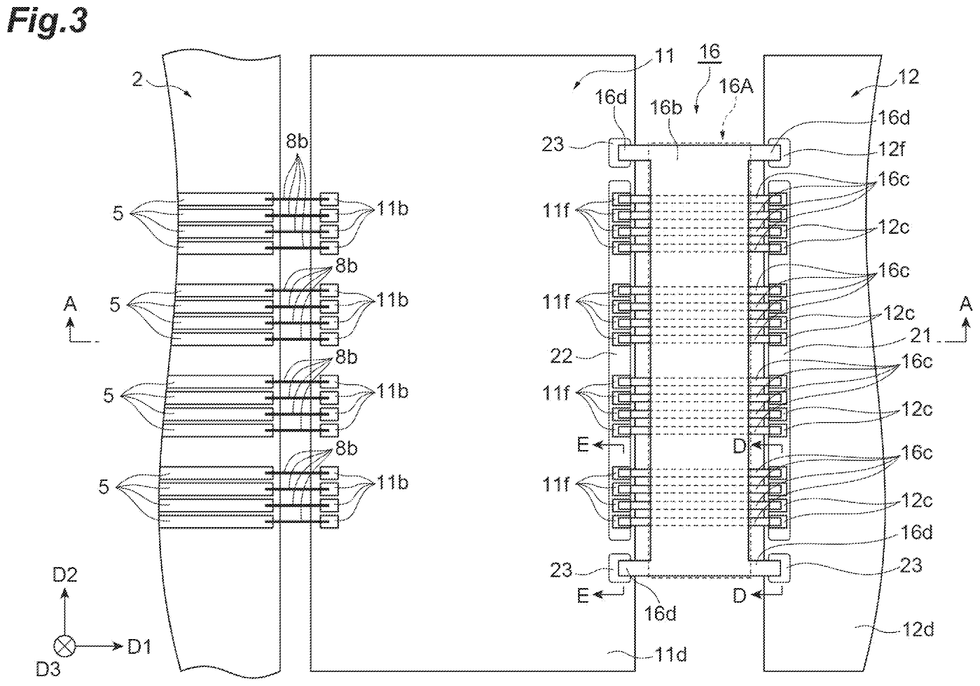

FIG. 3 is an enlarged plan view showing the flexible substrate 16, the driver IC 11, and the optical circuit element 12. As shown in FIG. 3, a pad 11f of the driver IC 11 is electrically connected to a pad 12c of the optical circuit element 12 via the flexible substrate 16. An electrical signal transmitted by the flexible substrate 16 has, for example, a band of 100 GHz or more. The flexible substrate 16 is, for example, a flexible printed circuit (FPC), and has flexibility. As will be described later, a thermal resistance of the FPC between the driver IC 11 and the optical circuit element 12 can be set to, for example, 100 K/W or more. Accordingly, the inflow of heat from the driver IC 11 to the optical circuit element 12 can be reduced, and a change in the optical characteristics of the optical circuit element 12 can be reduced.

In the package 2, the plurality of terminals 5 are disposed to align along the second direction D2. In the driver IC 11, a plurality of the pads 11b are aligned along the second direction D2. A plurality of the bonding wires 8b are aligned along the second direction D2, and each bonding wire 8b electrically connects the terminal 5 and the pad 11b to each other. As one example, the number of the terminals 5, the bonding wires 8b, and the pads 11b is 16.

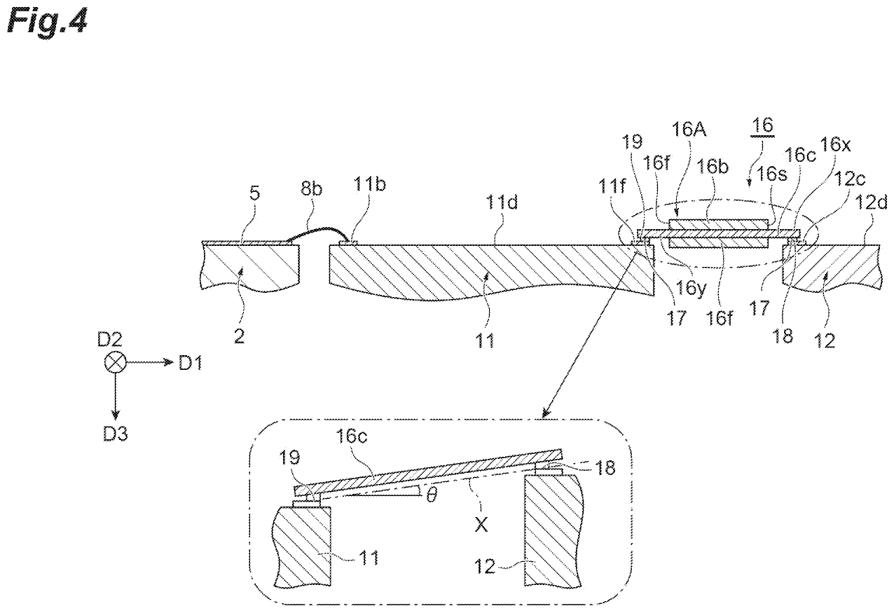

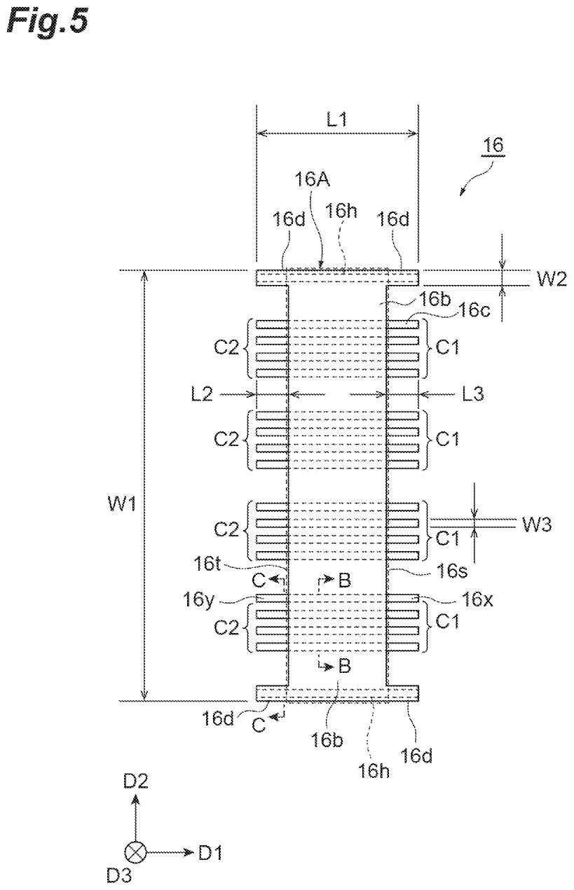

FIG. 4 is a cross-sectional view taken along line A-A of FIG. 3. FIG. 5 is a plan view of the flexible substrate 16 when the flexible substrate 16 is viewed along the third direction D3. As shown in FIGS. 4 and 5, the flexible substrate 16 includes a main body 16A and a wiring 16c. For example, the main body 16A includes at least a base film 16b to be described later. For example, the base film 16b is made of polyimide. However, the base film 16b may contain liquid crystal polymer (LCP) or polytetrafluoroethylene (as one example, Teflon (registered trademark)). The main body 16A extends in both the first direction D1 and the second direction D2. For example, when viewed along the third direction D3, the main body 16A has a rectangular shape. The main body 16A includes a first end 16s facing the optical circuit element 12, and a second end 16t facing the driver IC 11.

The flexible substrate 16 includes a plurality of the wirings 16c. The plurality of wirings 16c are aligned along the second direction D2. Each wiring 16c includes a first lead portion 16x that protrudes from the first end 16s to the outside of the main body 16A along the first direction D1, and a second lead portion 16y that protrudes from the second end 16t to the outside of the main body 16A along the first direction D1. The first lead portion 16x is connected to the optical circuit element 12. The second lead portion 16y is connected to the driver IC 11. The first lead portion 16x includes a first joint portion 18 connected to the pad 12c of the optical circuit element 12, and the second lead portion 16y includes a second joint portion 19 connected to the pad 11f of the driver IC 11. An inclination θ of a straight line X passing through the first joint portion 18 and the second joint portion 19 with respect to the first surface 2f is, for example, 10° or less. The first joint portion 18 and the second joint portion 19 will be described in detail later.

The flexible substrate 16 includes reinforcing portions 16d that protrude from respective four corners of the main body 16A along the first direction D1 when viewed along the third direction D3. The reinforcing portions 16d are formed to be bridged between the driver IC 11 and the optical circuit element 12, and are connected to the driver IC 11 and the optical circuit element 12. Two reinforcing portions 16d are disposed to interpose the first lead portion 16x therebetween along the second direction D2. Two reinforcing portions 16d are disposed to interpose the second lead portion 16y therebetween along the second direction D2. For example, a length of the reinforcing portion 16d in the first direction D1 is substantially the same as or longer than a length of the wiring 16c in the first direction D1. The reinforcing portions 16d include dummy wirings 16h. For example, a width W2 (length in the second direction D2) of the reinforcing portion 16d is wider than a width of the wiring 16c. For example, the shape, size, and material of the dummy wiring 16h are the same as the shape, size, and material of the wiring 16c. The reinforcing portion 16d includes, for example, at least one of the base film 16b, a protection film 16f, and the dummy wiring 16h to be described later.

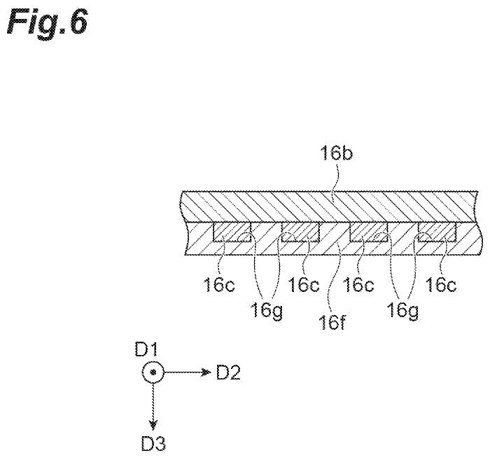

FIG. 6 is a cross-sectional view taken along line B-B of FIG. 5. As shown in FIGS. 5 and 6, for example, the main body 16A includes the base film 16b and the protection film 16f that interpose the wirings 16c along the third direction D3. For example, the base film 16b is made of polyimide. A thickness (length in the third direction D3) of the base film 16b may be, for example, 200 μm or less, 100 μm or less, 50 μm or less, or 25 μm or less.

For example, the wirings 16c form a single layer. Namely, the wirings 16c are not aligned in the third direction D3. The single layer of wirings 16c is formed on the base film 16b. In a cross section taken along a plane extending in both the second direction D2 and the third direction D3, one surface of each wiring 16c faces the base film 16b, and the remaining three surfaces of each wiring 16c face the protection film 16f. For example, the protection film 16f is formed to cover the three surfaces of each wiring 16c. In the case of a transmission line formed of a single layer of electrical wirings, an electric field is unevenly distributed between the electrical wirings, so that the electric field may be affected by the dielectric loss of the protection film 16f with respect to the base film 16b. In order to reduce the influence of the dielectric loss of the protection film 16f, the protection film 16f may be omitted. In this case, for example, the surfaces of the wirings 16c exposed due to the omission of the protection film 16f is plated with gold (Au).

In the present embodiment, the protection film 16f is made of, for example, a solder resist. In addition, the protection film 16f may be formed of, for example, a coverlay. A thickness of the protection film 16f is, for example, 25 μm. In the optical module 1, for example, the base film 16b is located above the wirings 16c (on a lid 6 side), and the protection film 16f is located below the wirings 16c (on a bottom wall 2h side). However, the base film 16b may be located below the wirings 16c, and the protection film 16f may be located above the wirings 16c.

The wirings 16c are interposed between the base film 16b and the protection film 16f. For example, a thickness (length in the third direction D3) of the wiring 16c is, for example, 20 μm. The thickness of the wiring 16c may be, for example, 50 μm or less, 40 μm or less, 30 μm or less, 20 μm or less, or 10 μm or less in order to improve thermal resistance to be described later. The wirings 16c are made of, for example, copper (Cu), and the surfaces of the wirings 16c are plated with gold (Au). In this case, ultrasonic joining between the wirings 16c and bumps 17 to be described later can be easily performed. A foundation metal layer may be formed between the copper constituting the wiring 16c and the gold constituting the surface of the wiring 16c. The foundation metal layer is made of, for example, nickel (Ni) and palladium (Pd). By forming the foundation metal layer between the copper and the gold of the wiring 16c, a decrease in connection reliability due to the copper or the like being deposited on the surface of the gold can be suppressed.

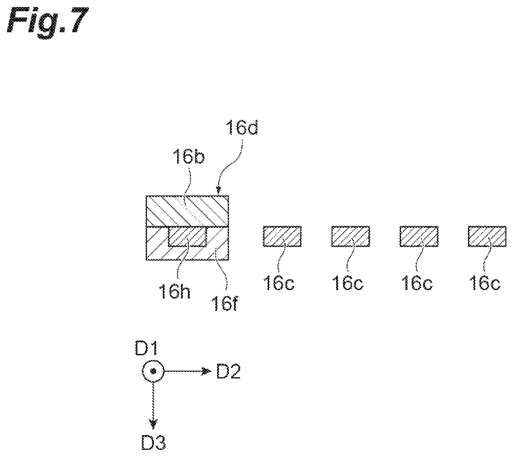

FIG. 7 is a cross-sectional view taken along line C-C of FIG. 5. As shown in FIGS. 5 and 7, each of the first lead portion 16x and the second lead portion 16y does not include the base film 16b and the protection film 16f. Terminals that do not include the base film 16b and the protection film 16f and that are formed of only electrical wirings, such as the first lead portion 16x and the second lead portion 16y, are referred to as flying leads, and a structure including the terminals is referred to as a flying lead structure. The FPC including flying leads is referred to as a flying lead FPC. In the flexible substrate 16 according to the present embodiment, a flying lead structure is formed at each of the first end 16s of the main body 16A and the second end 16t of the main body 16A.

The flexible substrate 16 includes a set C1 formed of a plurality of the first lead portions 16x aligned along the second direction D2, and a plurality of the sets C1 are aligned along the second direction D2. As one example, the number of the first lead portions 16x forming the set C1 and the number of the sets C1 are 4. The flexible substrate 16 includes a set C2 formed of a plurality of the second lead portions 16y aligned along the second direction D2, and a plurality of the sets C2 are aligned along the second direction D2. As one example, the number of the second lead portions 16y forming the set C2 and the number of the sets C2 are 4.

For example, in the set C1 and the set C2, a single-layer coplanar line having a ground-signal-signal-ground (GSSG) configuration is formed. In the flexible substrate 16, for example, the single-layer coplanar line having the GSSG configuration forms four channels. Each channel transmits two signals, so that differential signals can be transmitted. Incidentally, the configuration of the transmission line is not limited to GSSG, and may be, for example, ground-signal-ground-signal-ground (GSGSG) or signal-signal (SS). The width of the wiring 16c can be changed as appropriate according to the configuration of the line and characteristic impedance.

For example, a length W1 of the flexible substrate 16 in the second direction D2 is 3 mm. A length (width) L1 of the flexible substrate 16 in the first direction D1 is 1 mm. A length (length in the first direction D1) L3 of the first lead portion 16x is, for example, 150 μm. A length (length in the first direction D1) L2 of the second lead portion 16y is, for example, 150 μm. The wirings 16c form a transmission line that transmits high-speed signals, and the wiring width and the wiring interval are designed such that the characteristic impedance has a desired value. In the present embodiment, the characteristic impedance may be substantially equal to the terminating resistance of the optical circuit element 12 that is an optical modulator, and the characteristic impedance is, for example, 50Ω or more and 70Ω or less (as one example, 60Ω) differentially. The width (length in the second direction D2) of the wiring 16c on the main body 16A is, for example, 80 μm, and an interval between the wirings 16c aligned along the second direction D2 is 20 μm. In this case, the wirings 16c are formed at a pitch of 100 μm along the second direction D2.

For example, a width W3 of the first lead portion 16x is 85 μm, and a wiring interval of the first lead portions 16x aligned along the second direction D2 is 15 μm. The same applies to the second lead portions 16y. By setting the wiring interval of the first lead portions 16x and the second lead portions 16y to be smaller than a wiring interval of portions of the wirings 16c other than the first lead portions 16x and the second lead portions 16y, the characteristic impedance can be made constant between the portions and both the first lead portions 16x and the second lead portions 16y.

A thermal resistance of the 16 wirings 16c forming the transmission line is approximately 100 K/W when it is assumed that the thickness (length in the third direction D3) of the wiring 16c is 20 μm, the length (length in the first direction D1) of the wiring 16c is 1 mm, the width (length in the second direction D2) of the wiring 16c is 80 μm, and the thermal conductivity of copper (Cu) constituting the wiring 16c is 400 W/(m·K).

On the other hand, a thermal resistance of the driver IC 11 in the third direction D3 is 0.15 K/W when it is assumed that the thermal conductivity of silicon (Si) constituting the driver IC 11 is 162 W/(m·K), the length of the driver IC 11 in the first direction D1 is 2 mm, the length of the driver IC 11 in the second direction D2 is 4 mm, and the length of the driver IC 11 in the third direction D3 is 0.2 mm. A thermal resistance of the heat sink block 13 in the third direction D3 is 0.8 K/W when it is assumed that the thermal conductivity of aluminum nitride constituting the heat sink block 13 is 200 W/(m·K), the length of the heat sink block 13 in the first direction D1 is 2 mm, the length of the heat sink block 13 in the second direction D2 is 4 mm, and the length of the heat sink block 13 in the third direction D3 is 1.2 mm. A series thermal resistance from the third surface 11d of the driver IC 11 to the bottom wall 2h (heat sink plate) is approximately 1 K/W in total, which is approximately 1/100 of the thermal resistance of the wirings 16c of the flexible substrate 16.

A thermal resistance of the optical circuit element 12 in the third direction D3 is 0.4 K/W when it is assumed that the thermal conductivity of indium phosphide (InP) constituting the optical circuit element 12 is 68 W/(m·K), the length of the optical circuit element 12 in the first direction D1 is 2 mm, the length of the optical circuit element 12 in the second direction D2 is 4 mm, and the length of the optical circuit element 12 in the third direction D3 is 0.2 mm. A thermal resistance of the spacer 14 in the third direction D3 is 0.1 K/W when it is assumed that the thermal conductivity of aluminum nitride constituting the spacer 14 is 200 W/(m·K), the length of the spacer 14 in the first direction D1 is 2 mm, the length of the spacer 14 in the second direction D2 is 4 mm, and the length of the spacer 14 in the third direction D3 is 0.2 mm. For this reason, a thermal resistance from the fourth surface 12d of the optical circuit element 12 to the bottom wall 2h (heat sink plate) is 1 K/W or less in total, which is 1/100 or less of the thermal resistance of the wiring 16c of the flexible substrate 16.

As described above, the influence of the inflow and outflow of heat between the driver IC 11 and the optical circuit element 12 is small. Incidentally, in order to suppress the inflow and outflow of heat between the driver IC 11 and the optical circuit element 12, as in the present embodiment, the total thermal resistance of the wirings 16c forming the transmission line may be larger than 100 K/W. The number of the wirings 16c, the thickness of the wiring 16c, the width of the wiring 16c, and the length of the wiring 16c may be designed such that the total thermal resistance is larger than 100 K/W.

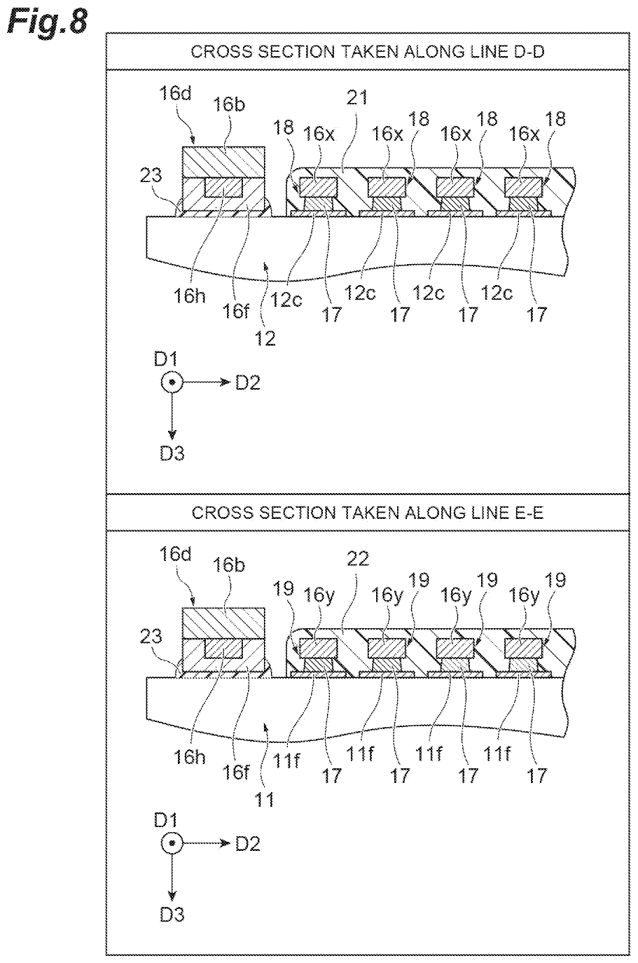

FIG. 8 shows a cross-sectional view taken along line D-D of FIG. 3, and a cross-sectional view taken along line E-E of FIG. 3. As shown in FIGS. 3 and 8, the first lead portions 16x of the wirings 16c are connected to the optical circuit element 12 via the bumps 17 formed on the optical circuit element 12. For example, the first lead portions 16x includes the first joint portions 18 connected to the pads 12c of the optical circuit element 12 via the bumps 17. The bumps 17 are, for example, Au stud bumps. As one example, the bump 17 has a columnar shape, and a diameter of the bump 17 is 50 μm. A height (length in the third direction D3) of the bump 17 is, for example, 10 μm.

For example, the bumps 17 are formed on the pads 12c by ultrasonic joining. For example, the pads 12c are made of gold (Au). For example, the first joint portions 18 are covered with resin 21. The resin 21 is, as one example, an ultraviolet curable resin. By covering the first joint portions 18 with the resin 21, joining between the first lead portions 16x and the bumps 17 and between the bumps 17 and the optical circuit element 12 can be strengthened, and an increase in the characteristic impedance of the first joint portions 18 can be suppressed. Incidentally, in a plan shown in FIG. 3, the resin 21 may be spaced apart from the first end 16s of the main body 16A. In this case, there remain portions of the first lead portions 16x, which are not covered with the resin 21, and flexibility can be maintained at the portions. However, even in a case where the resin 21 is in contact with the first end 16s of the main body 16A, when the resin 21 has elasticity, the first lead portions 16x have flexibility.

The second lead portions 16y of the wirings 16c are connected to the driver IC 11 via the bumps 17 formed on the driver IC 11. The second lead portions 16y include, for example, the second joint portions 19 connected to the pads 11f of the driver IC 11 via the bumps 17. The bumps 17 are formed on the pads 11f by ultrasonic joining. The pads 11f are made of, for example, aluminum (Al). When the bumps 17 are formed on the pads 11f by ultrasonic joining, even if the surfaces of the pads 11f are oxidized, the oxide films are broken, so that highly reliable electrical connection becomes possible. For example, the second joint portions 19 are covered with the same resin 22 as the resin 21 described above. Therefore, by covering the second joint portions 19 with the resin 22, joining between the second lead portions 16y and the bumps 17 and between the bumps 17 and the driver IC 11 can be strengthened, and an increase in the characteristic impedance of the second joint portions 19 can be suppressed. Similarly to the resin 21, the resin 22 may be also spaced apart from the second end 16t of the main body 16A. In this case, there remain portions of the second lead portions 16y, which are not covered with the resin 22, and flexibility can be maintained at the portions. However, even in a case where the resin 22 is in contact with the second end 16t of the main body 16A, when the resin 22 has elasticity, the second lead portions 16y have flexibility.

Since the first lead portions 16x, the second lead portions 16y, and the bumps 17 do not include the base film 16b and the protection film 16f, the characteristic impedance of the transmission line may increase. However, by providing the resin 21 and the resin 22, an increase in characteristic impedance due to an increase in capacitance between the electrical wirings can be suppressed. When the influence of joint strength or characteristic impedance is small, at least one of the resin 21 and the resin 22 may be omitted. For example, the reinforcing portions 16d are fixed to the driver IC 11 and the optical circuit element 12 by resin 23. The resin 23 is, for example, an ultraviolet curable resin. The reinforcing portions 16d may not be electrically connected to the driver IC 11 and the optical circuit element 12. Incidentally, the resin 23 may be a sheet-shaped adhesive or may be resin formed on the reinforcing portions 16d in advance.

Incidentally, in order to suppress short circuit between the wirings 16c, the width of the first lead portions 16x may be narrowed at the first joint portions 18, and the interval between the first lead portions 16x may be widened. The same applies to the second joint portions 19 and the second lead portions 16y. Even in this case, by using the resin 21 and the resin 22, an increase in the characteristic impedance of the first joint portions 18 and the second joint portions 19 can be suppressed.

The flexibility of the first lead portions 16x is larger than the flexibility of the main body 16A, and the flexibility of the second lead portions 16y is larger than the flexibility of the main body 16A. The electrical wirings of the first lead portions 16x and the electrical wirings of the second lead portions 16y do not include the base film 16b and the protection film 16f, can be deformed independently of each other, and have higher flexibility than portions of the flexible substrate 16 including the base film 16b, the wirings 16c, and the protection film 16f. With the flying lead FPC having excellent flexibility in such a manner, even when a height K1 of the driver IC 11 (refer to FIG. 2) is different from a height K2 of the optical circuit element 12 (for example, by approximately 100 μm), the driver IC 11 can be electrically connected to the optical circuit element 12 in a stable manner.

More specifically, due to variations in components, or the like, the difference between the height K1 of the driver IC 11 and the height K2 of the optical circuit element 12 may be approximately 100 μm. For example, when it is assumed that the length of the flexible substrate 16 in the first direction D1 is 1 mm as described above, the inclination θ shown in FIG. 4 is approximately 6°. Further, as described above, it is assumed that the difference between the height K1 of the driver IC 11 and the height K2 of the optical circuit element 12 increases due to thermal contraction or thermal expansion accompanying a change in temperature. In addition, as described above, it is assumed that the distance between the driver IC 11 and the optical circuit element 12 in the first direction D1 changes. For this reason, when a wiring substrate in which electrical connection between the driver IC 11 and the optical circuit element 12 has low flexibility is used, there is a possibility that large stress occurs in joint portions, thereby causing reliability problems. However, when the flexible substrate 16 is used, the first lead portions 16x and the second lead portions 16y are more easily flexed than the main body 16A, so that the reliability of electrical connection between the driver IC 11 and the optical circuit element 12 can be increased. In addition, even when stress occurs in the flexible substrate 16 due to a change in temperature or the like, the stress can be relieved due to the first lead portions 16x and the second lead portions 16y being deformed in addition to the main body 16A. Incidentally, in order to further increase flexibility, at least one of the first lead portions 16x and the second lead portions 16y may be flexed in advance.

Next, an example of a manufacturing method for manufacturing the optical module 1 by assembling the flexible substrate 16 will be described. For example, the bumps 17 are formed on the pads 11f of the driver IC 11 and the pads 12c of the optical circuit element 12 (a step of forming bumps). Next, the flexible substrate 16 is mounted to be bridged between the driver IC 11 and the optical circuit element 12. Then, the reinforcing portions 16d are fixed to the driver IC 11 by the resin 23, and the reinforcing portions 16d are fixed to the optical circuit element 12 by the resin 23 (a step of mechanically fixing the driver IC and the flexible substrate, and the optical circuit element and the flexible substrate).

Then, the flexible substrate 16 is connected to the driver IC 11 by mounting the second lead portions 16y on the bumps 17 of the pads 11f, and the flexible substrate 16 is connected to the optical circuit element 12 by mounting the first lead portions 16x on the bumps 17 of the pads 12c (a step of electrically connecting the driver IC and the flexible substrate, and the optical circuit element and the flexible substrate). The mounting of the first lead portions 16x on the bumps 17 and the mounting of the second lead portions 16y on the bumps 17 are realized, for example, by ultrasonically joining the gold on the surfaces of the first lead portions 16x and the second lead portions 16y and the gold on the bumps 17 using an ultrasonic mounting machine such as a wedge bonder. By using the bumps 17 that are thick and easily deformed, highly reliable electrical connection between the first lead portions 16x and the pads 12c and between the second lead portions 16y and the pads 11f is made possible. Thereafter, a series of the steps are completed. Incidentally, the order in which the flexible substrate 16 is connected to the driver IC 11 and the optical circuit element 12 is not limited to the above example, and can be changed as appropriate. For example, the mounting of the first lead portions 16x on the bumps 17 and the mounting of the second lead portions 16y on the bumps 17 may be realized by a thermocompression bonding method.

Subsequently, actions and effects obtained from the optical module 1 and the flexible substrate 16 will be described. The optical module 1 and the flexible substrate 16 include the main body 16A and the wirings 16c, and the main body 16A includes the first end 16s facing the optical circuit element 12. The wirings 16c include the first lead portions 16x. The first lead portions 16x protrude from the first end 16s of the main body 16A to the outside of the main body 16A along the first direction D1, and are connected to the optical circuit element 12. By connecting the first lead portions 16x of the wirings 16c of the flexible substrate 16 to the optical circuit element 12, the first lead portions 16x protruding from the main body 16A and the first end 16s are flexed even when a change in position occurs due to a change in temperature or the like, so that the influence of stress on the driver IC 11 and the optical circuit element 12 can be reduced. Therefore, the robustness of electrical connection between the driver IC 11 and the optical circuit element 12 can be improved.

In the present embodiment, the flexibility of the first lead portions 16x is larger than the flexibility of the main body 16A. In this case, since the first lead portions 16x can be flexed more greatly when a change in temperature or the like occurs, the robustness of the electrical connection between the driver IC 11 and the optical circuit element 12 can be further improved.

In the present embodiment, the first lead portions 16x include the first joint portions 18 connected to the optical circuit element 12 via the bumps 17 formed on the optical circuit element 12. In this case, since the first lead portions 16x of the flexible substrate 16 are connected to the optical circuit element 12 via the bumps 17, the electrical connection between the driver IC 11 and the optical circuit element 12 can be made even more reliable. When the bumps 17 are stud bumps, stress can also be relieved at the bumps 17 due to the stud bumps having elasticity, thereby contributing to further improvement in robustness.

In the present embodiment, the flexible substrate 16 includes the reinforcing portions 16d disposed to interpose the first lead portions 16x therebetween along the second direction D2, and the reinforcing portions 16d are connected to the optical circuit element 12. For example, the reinforcing portions 16d include the base film 16b, the wirings 16c, and the protection film 16f. In this case, the connection of the flexible substrate 16 to the optical circuit element 12 can be reinforced.

In the present embodiment, the reinforcing portions 16d include the dummy wirings 16h. In this case, the strength of the reinforcing portions 16d can be improved compared to when the dummy wirings 16h are not included. When the material of the dummy wirings 16h is the same as the material of the wirings 16c, the difference between the linear expansion coefficient of the reinforcing portions 16d and the linear expansion coefficient of the first lead portions 16x can be reduced. Further, the difference between the linear expansion coefficient of the reinforcing portions 16d and the linear expansion coefficient of the second lead portions 16y can be reduced. As a result, the difference in expansion and contraction in the first direction D1 between the reinforcing portions 16d, the first lead portions 16x, and the second lead portions 16y due to a change in temperature can be reduced. Therefore, in a wide temperature range, most of a force (particularly, a tensile force) applied to the flexible substrate 16 in the first direction D1 can be borne by the reinforcing portions 16d, and a force applied to the wirings 16c can be effectively reduced. Accordingly, the robustness of the electrical connection between the driver IC 11 and the optical circuit element 12 can be improved. In order to effectively reduce the force applied to the wirings 16c, the width of the dummy wirings 16h in the reinforcing portions 16d may be wider than the width of the wirings 16c. The dummy wiring 16h may be continuously formed from the reinforcing portion 16d on a first end 16s side of the main body 16A to the reinforcing portion 16d on a second end 16t side.

In the present embodiment, the reinforcing portions 16d include the protection film 16f, and the protection film 16f faces the driver IC 11 (or the optical circuit element 12). Therefore, compared to when the reinforcing portions 16d do not include the protection film 16f, the difference between a height of the dummy wirings 16h and a height of the wirings 16c can be reduced. As a result, stress caused by deformation of the first lead portions 16x and the second lead portions 16y can be reduced, so that connection reliability can be further improved. Incidentally, the flexible substrate 16 may be disposed such that the base film 16b faces the driver IC 11 (or the optical circuit element 12). In this case, even when the protection film 16f is omitted, the difference between the height of the dummy wirings 16h and the height of the wirings 16c can be reduced.

In the present embodiment, the main body 16A includes the second end 16t opposite to the first end 16s, and the wirings 16c include the second lead portions 16y that protrude from the second end 16t to the outside of the main body 16A along the first direction D1. The second lead portions 16y are connected to the driver IC 11. In this case, the main body 16A includes the second end 16t facing the driver IC 11, and the wirings 16c include the second lead portions 16y. The second lead portions 16y protrude from the second end 16t of the main body 16A to the outside of the main body 16A along the first direction D1, and are connected to the driver IC 11. By connecting the second lead portions 16y of the wirings 16c of the flexible substrate 16 to the driver IC 11, the second lead portions 16y protruding from the main body 16A and the second end 16t are flexed even when a change in temperature or the like occurs, so that the electrical connection between the driver IC 11 and the optical circuit element 12 can be made highly reliable. In such a manner, the same actions and effects as those of the first lead portions 16x described above are obtained from the second lead portions 16y.

In the present embodiment, the first lead portions 16x include the first joint portions 18 connected to the optical circuit element 12 via the bumps 17 formed on the optical circuit element 12, and the second lead portions 16y include the second joint portions 19 connected to the driver IC 11 via the bumps 17 formed on the driver IC 11. The inclination θ of the straight line X passing through the first joint portion 18 and the second joint portion 19 with respect to the first surface 2f is 10° or less. In this case, the robustness of the electrical connection between the driver IC 11 and the optical circuit element 12 via the flexible substrate 16 can be further improved.

In the present embodiment, the first joint portions 18 are covered with the resin 21, and the second joint portions 19 are covered with the resin 22. The resin 21 and the resin 22 have a higher joint strength than ultrasonic joining using stud bumps. In this case, the first joint portions 18 and the second joint portions 19 can be further strengthened. The first joint portions 18 are mechanically fixed to the optical circuit element 12 by the resin 21, and the second joint portions 19 are mechanically fixed to the driver IC 11 by the resin 22.

Next, various modification examples of the optical module according to the present disclosure will be described. A part of the configuration of optical modules according to various modification examples to be described later is the same as a part of the configuration of the optical module 1 described above. Therefore, hereinafter, descriptions that overlap with the description of the optical module 1 are denoted by the same reference signs, and will be omitted as appropriate.

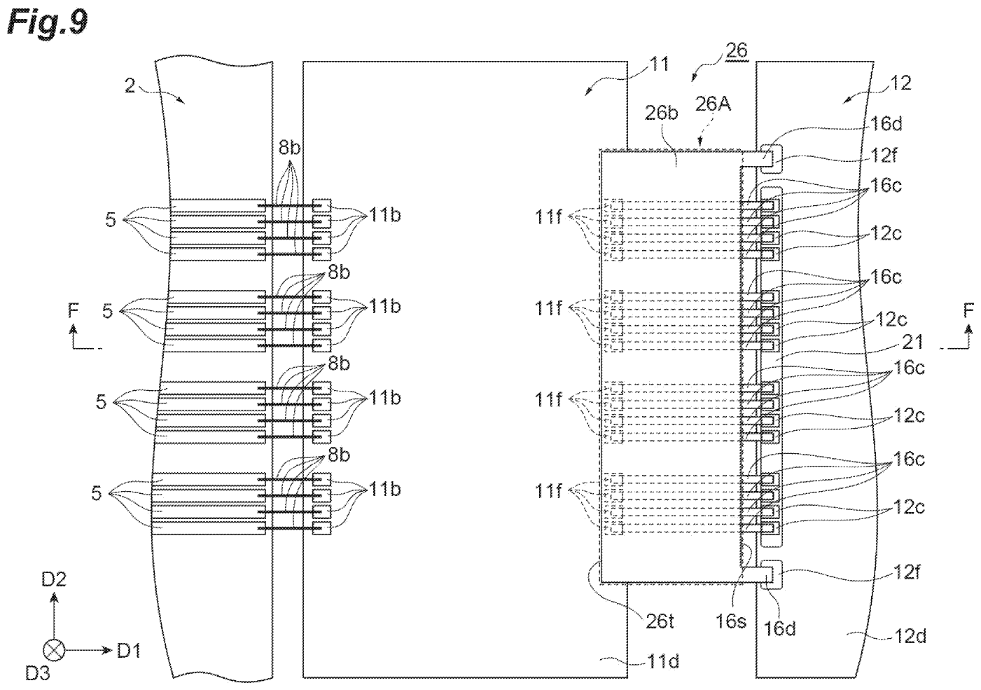

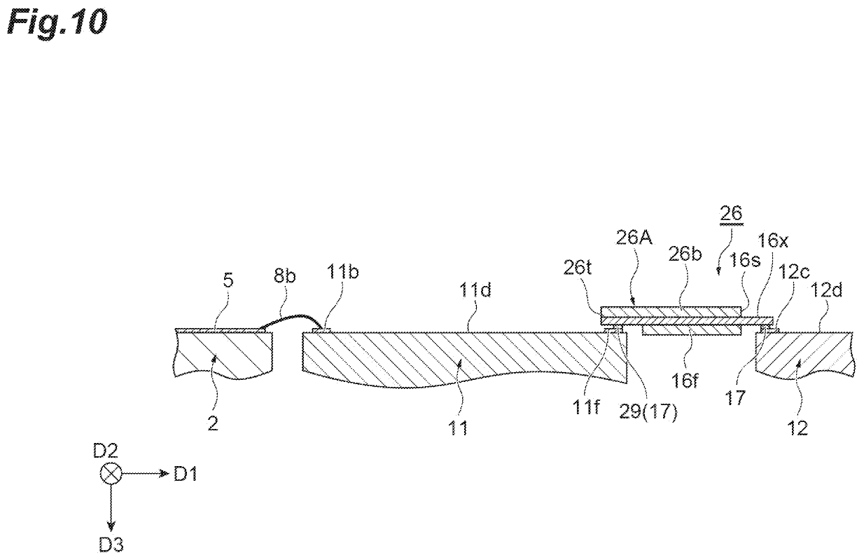

FIG. 9 is an enlarged plan view showing a flexible substrate 26 and the driver IC 11 of an optical module according to a first modification example. FIG. 10 is a cross-sectional view taken along line F-F of FIG. 9. The flexible substrate 26 includes the first lead portions 16x that protrude from the first end 16s facing the optical circuit element 12 to the outside of a main body 26A along the first direction D1. In the flexible substrate 26, the wirings 16c do not protrude from a second end 26t facing the driver IC 11. Namely, the flexible substrate 26 differs from the flexible substrate 16 in that the flexible substrate 26 does not include the second lead portions 16y.

The second end 26t of the flexible substrate 26 is formed of a base film 26b and the wirings 16c. The protection film 16f is removed from a portion of the main body 26A facing the driver IC 11. The portion of the main body 26A which faces the driver IC 11 and from which the protection film 16f is removed is a joint portion 29 that is joined to the driver IC 11. At the joint portion 29, the main body 26A is connected to the pads 11f of the driver IC 11 via the bumps 17. The joint portion 29 may be protected by resin.

An example of a method for manufacturing an optical module according to the first modification example will be described. First, an integral component of the driver IC 11 and the flexible substrate 26 is manufactured. Specifically, the driver IC 11 is flip-chip mounted on the flexible substrate 26. The pads 11f of the driver IC 11 and the wirings 16c of the flexible substrate 26 are ultrasonically joined via the bumps 17. Incidentally, regarding the mounting of the flexible substrate 26 on the driver IC 11, the flexible substrate 26 may be flipped and mounted on the driver IC 11. In addition, a method for connecting the pads 11f of the driver IC 11 and the wirings 16c of the flexible substrate 26 via the bumps 17 may be thermocompression bonding instead of ultrasonic joining.

Next, the integral component of the driver IC 11 and the flexible substrate 26 is mounted on the package 2, a substrate surface of the driver IC 11 is bonded and fixed to the heat sink block 13, and then the flexible substrate 26 is joined to the optical circuit element 12. Specifically, after the reinforcing portions 16d are fixed to the optical circuit element 12, the first lead portions 16x of the flexible substrate 26 are ultrasonically joined to the pads 12c of the optical circuit element 12 via the bumps 17. The assembly of the optical module is completed through the above steps. For example, silver paste can be used to bond and fix the driver IC 11 and the heat sink block 13.

As described above, in the optical module and the flexible substrate 26 according to the first modification example, the flying lead structure is formed only at the first end 16s of the main body 26A, and the flying lead structure is not formed at the second end 26t. Namely, the wirings 16c do not include the second lead portions 16y, but only include the first lead portions 16x. In this case as well, the same actions and effects as those of the optical module 1 are obtained. Incidentally, unlike the above description, the optical module may be configured such that the flying lead structure is formed only at the second end of the main body and the flying lead structure is not formed at the first end. In this case, the wirings do not include the first lead portions 16x, but only include the second lead portions 16y.

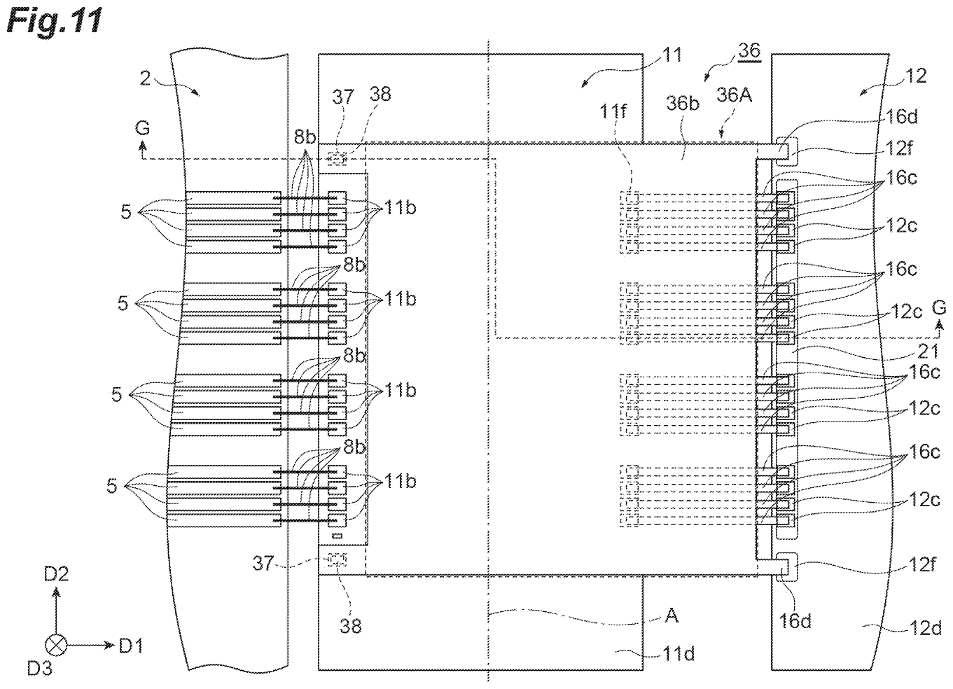

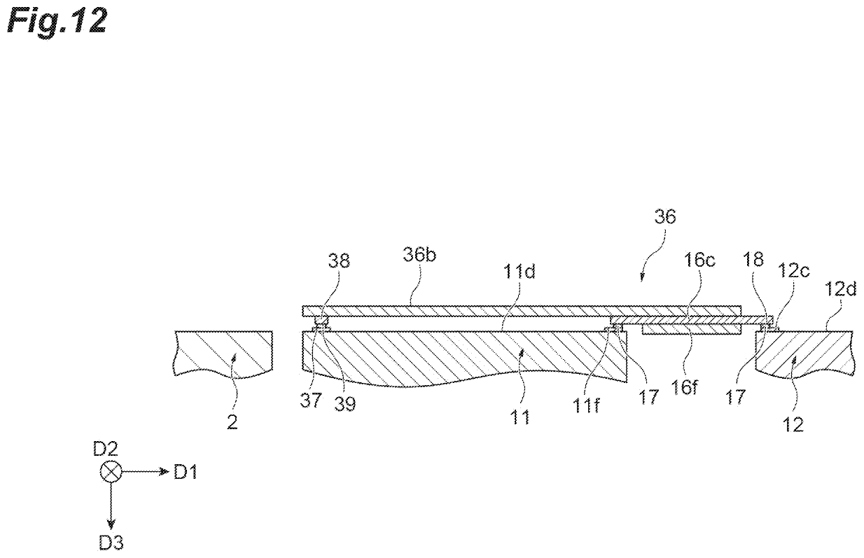

FIG. 11 is an enlarged plan view showing a flexible substrate 36 and the driver IC 11 of an optical module according to a second modification example. FIG. 12 is a cross-sectional view taken along line G-G of FIG. 11. The flexible substrate 36 includes a main body 36A that extends to a position closer to the package 2 than the center of the driver IC 11 in the first direction D1 when viewed along the third direction D3. A base film 36b of the main body 36A extends to a position closer to the package 2 than a reference line A that passes through the center of the driver IC 11 in the first direction D1 when viewed along the third direction D3 and that extends along the second direction D2. The flexible substrate 36 includes fixing portions 38 connected to the main body 36A and aligned along the second direction D2. The fixing portions 38 are fixed to pads 37 formed on the third surface 11d of the driver IC 11 via bumps 39. In the flexible substrate 36, the number of the points of connection of the main body 36A to the driver IC 11 is larger than that in the flexible substrate 26, so that the flexible substrate 36 and the driver IC 11 can be more stably connected, and robustness can be improved.

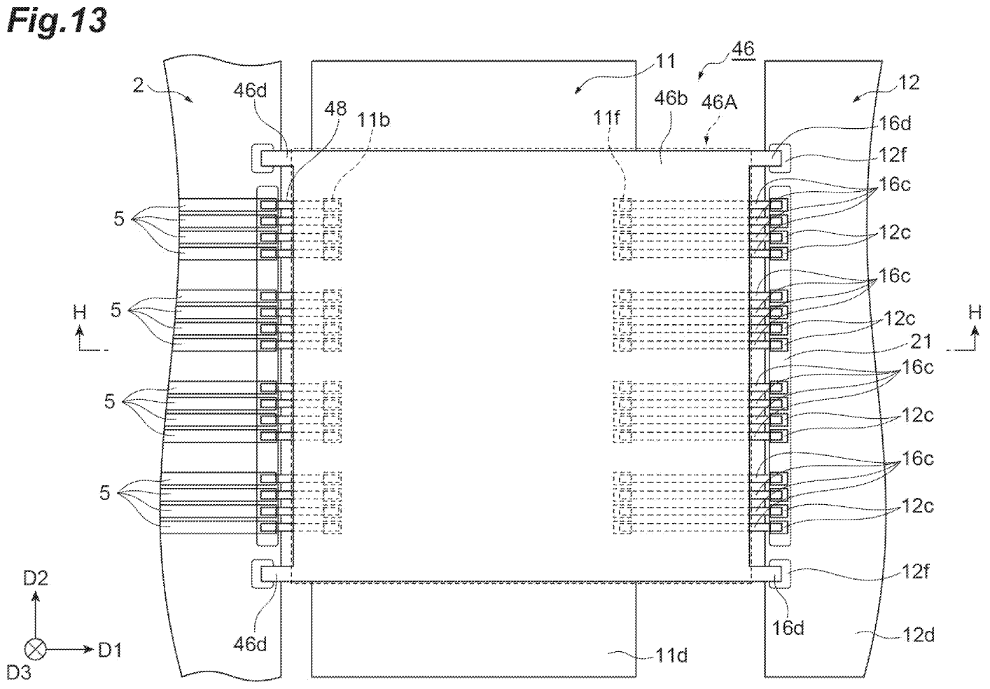

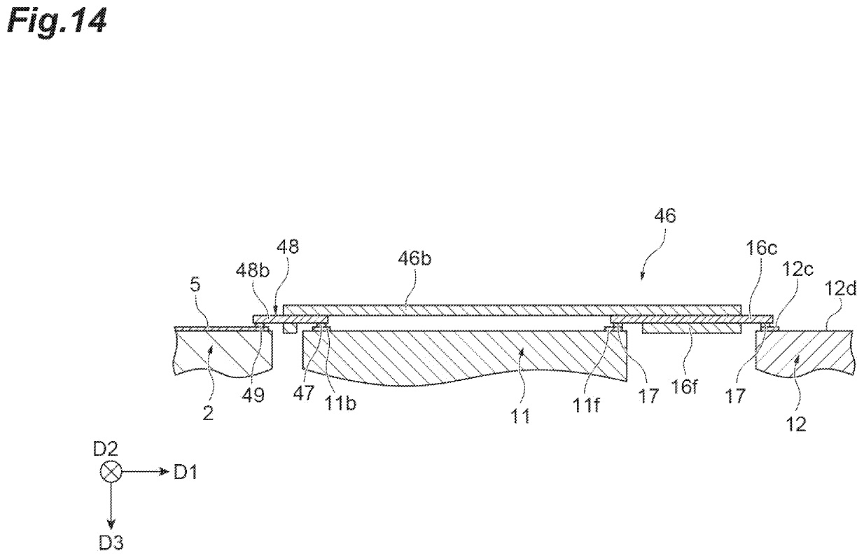

FIG. 13 is an enlarged plan view showing a flexible substrate 46 and the driver IC 11 of an optical module according to a third modification example. FIG. 14 is a cross-sectional view taken along line H-H of FIG. 13. The flexible substrate 46 includes a main body 46A extending from the optical circuit element 12 beyond the driver IC 11 to near the package 2 when viewed along the third direction D3. A base film 46b of the main body 46A is disposed to cover the entirety of the driver IC 11 in the first direction D1. The flexible substrate 46 includes a plurality of wirings 48 aligned along the second direction D2. The wirings 48 are disposed to be bridged between the pads 11b of the driver IC 11 and the terminals 5 of the package 2. The flexible substrate 46 includes reinforcing portions 16d and 46d that protrude from respective four corners of the main body 46A along the first direction D1 when viewed along the third direction D3. The reinforcing portions 16d are formed to be bridged to the optical circuit element 12, and are connected to the optical circuit element 12. The reinforcing portions 46d are formed to be bridged to the package 2, and are connected to the package 2.

The wirings 48 are fixed to the pads 11b of the driver IC 11 via bumps 47, and are fixed to the terminals 5 of the package 2 via bumps 49. Similarly to the wirings 16c described above, the wirings 48 include third lead portions 48b that are flying leads (do not include the base film 46b and the protection film 16f), and the third lead portions 48b are joined to the terminals 5 via the bumps 49. For example, the joining of the third lead portions 48b to the terminals 5 is the same as the joining of the first lead portions 16x to the pads 12c described above. In the flexible substrate 46, the terminals 5 of the package 2 are electrically connected to the pads 11b of the driver IC 11 via the wirings 48, so that the bonding wires 8b described above can be made unnecessary. Therefore, high-frequency connection between the package 2 and the driver IC 11 becomes possible. In order to realize high-frequency connection between the package 2 and the driver IC 11, the wiring width and the interval between adjacent wirings of the wirings 48 on the main body 46A and the third lead portions 48b are appropriately designed. The characteristic impedance of the wirings 48 may be substantially equal to the input terminating resistance of the driver IC 11, and is, for example, 90Ω or more and 110Ω or less (as one example, 100Ω) differentially.

The embodiment and various modification examples of the optical module and the flexible substrate according to the present disclosure have been described above. However, the present invention is not limited to the embodiment or the various modification examples described above, and can be changed as appropriate within the scope of the concept described in the claims. In addition, the optical module and the flexible substrate according to the present disclosure may be a combination of a plurality of examples from the embodiment and the first to third modification examples described above. For example, the configuration, shape, size, material, number, and disposition mode of each part of the optical module and the flexible substrate according to the present disclosure are not limited to the embodiment or the modification examples described above, and can be changed as appropriate.

For example, in the embodiment described above, the flexible substrate 16 including a single layer of the wirings 16c has been described. However, the flexible substrate may include two or more layers of wirings. In the embodiment described above, the flexible substrate 16 in which the two reinforcing portions 16d are provided at positions interposing the plurality of wirings 16c therebetween aligned along the second direction D2 has been described. However, the disposition of the wirings and the reinforcing portions of the flexible substrate can be changed as appropriate. In the embodiment described above, an example in which the flexible substrate 16 is provided in the optical module 1 that is a transmitter optical sub-assembly including the package 2 having a rectangular parallelepiped shape, the optical connector 3, and the terminals 4 has been described. However, the flexible substrate 16 according to the present disclosure can also be applied to optical modules other than the transmitter optical sub-assembly.

What is claimed is:

1. An optical module comprising:
a package having a first surface and a second surface parallel to the first surface;
a driver IC mounted on the first surface via a heat sink block;
an optical circuit element mounted on the second surface via a temperature adjustment element; and
a flexible substrate mounted on the driver IC and the optical circuit element, and electrically connected to the driver IC and the optical circuit element,
wherein the flexible substrate includes a main body extending in a first direction and a second direction intersecting the first direction, and a wiring formed on the main body,
the main body includes a first end facing the optical circuit element,
the wiring includes a first lead portion protruding from the first end to an outside of the main body along the first direction, and
the first lead portion is connected to the optical circuit element.

2. The optical module according to claim 1,
wherein a flexibility of the first lead portion is larger than a flexibility of the main body.

3. The optical module according to claim 1,
wherein the first lead portion includes a first coupling portion connected to the optical circuit element via a bump formed on the optical circuit element.

4. The optical module according to claim 1,
wherein the flexible substrate includes reinforcing portions protruding from the main body, and disposed to interpose the first lead portion between the reinforcing portions along the second direction, and
the reinforcing portions are connected to the optical circuit element.

5. The optical module according to claim 4,
wherein the reinforcing portions include dummy wirings.

6. The optical module according to claim 1,
wherein the main body includes a second end opposite to the first end,
the wiring includes a second lead portion protruding from the second end to the outside of the main body along the first direction, and
the second lead portion is connected to the driver IC.

7. The optical module according to claim 6,
wherein the first lead portion includes a first coupling portion connected to the optical circuit element via a bump formed on the optical circuit element,
the second lead portion includes a second coupling portion connected to the driver IC via a bump formed on the driver IC, and
an inclination of a straight line passing through the first coupling portion and the second coupling portion with respect to the first surface is 10° or less.

8. The optical module according to claim 7,
wherein the first coupling portion and the second coupling portion are covered with resin.

9. An optical module comprising:
a package having a first surface and a second surface parallel to the first surface;
a driver IC mounted on the first surface via a heat sink block;
an optical circuit element mounted on the second surface via a temperature adjustment element; and
a flexible substrate mounted on the driver IC and the optical circuit element, and electrically connected to the driver IC and the optical circuit element,
wherein the flexible substrate includes a main body extending in a first direction and a second direction intersecting the first direction, and a wiring formed on the main body,
the main body includes a second end facing the driver IC,
the wiring includes a second lead portion protruding from the second end to an outside of the main body along the first direction, and
the second lead portion is connected to the driver IC.

10. A flexible substrate comprising:
a main body extending in a first direction and a second direction intersecting the first direction; and
a wiring formed on the main body,
wherein the main body includes a first end facing an optical circuit element,
the wiring includes a first lead portion protruding from the first end to an outside of the main body along the first direction, and
the first lead portion is connected to the optical circuit element.
